(19) United States
(12) Patent Application Publication
(10) Pub. No.: US 2006/0227508 A1
(43) Pub. Date: Oct. 12, 2006

(54) Heat sink assembly

(75) Inventor: Craig Warren Hornung, Harrisburg, PA (US)

Correspondence Address: Robert J. Kapalka;Tyco Electronics Corporation, Suite 140, 4550 New Linden Hill, Wilmington, DE, 19808-2952, US

(73) Assignee: Tyco Electronics Corporation

(21) Appl. No.: 11/102,124

(22) Filed: Apr. 8, 2005

(51) Int. Cl. H05K 7/20

(52) U.S. Cl. 361/703; 257/722; 165/80.3; 165/185

(57) ABSTRACT

A heat sink assembly includes a base having first and second surfaces, and a dimension therebetween extending substantially perpendicular to each of the first and second surfaces. The base includes an opening extending therethrough and an insert received in the opening, wherein the insert has opposite first and second surfaces separated by a distance substantially equal to the dimension. The base is fabricated from a first material and the insert is fabricated from a second material. Optionally, the base may be fabricated from aluminum, and the insert may be fabricated from copper. Additionally, the base may be substantially rectangular, and the insert may be substantially circular, wherein the base surrounds the insert.

### BACKGROUND OF THE INVENTION

This invention relates generally to a heat sink assembly, and more particularly, to a heat sink assembly having an improved thermal performance geometry.

The use of heat sinks on electronic components is known. Typically, a heat sink is arranged in close contact with an electronic component, such as a processor chip. Heat generated by the component is transferred to the heat sink and dissipated therefrom. One type of heat sink includes a metallic core in the form of a base plate. Heat dissipating fins extend from the base plate to increase the surface area of the heat sink. Heat transferred from the component to the base plate is spread throughout the base plate and to the fins fixed to the base plate. A fan element circulates air about outer surfaces of the fins and the base to facilitate the transfer of heat from the fins to the air, thereby dissipating heat from the electronic component.

For improved performance, some types of heat sink cores include a cylindrical or rectangular insert or slug in the base plate that is fabricated from a different material (e.g., copper or silver) having a higher thermal conductivity than the base plate, typically fabricated from aluminum. The insert increases the thermal conductivity of the base plate and reduces spreading resistance that inhibits rapid heating of the base plate.

Typically a cavity is defined within the base and the insert is press fit into the cavity. The insert is typically positioned in direct contact with the electronic component to transfer the heat generated by the component into the heat sink. Generally, the base plate surrounds the sides and the top of the insert such that a large area of contact is defined between the surfaces of the insert and the base plate. This aids in transferring the heat from the insert to the base plate. Moreover, the heat is then transferred through the base plate to the heat dissipating fins coupled to the top surface of the base plate. However, the interface of the insert and the base plate can itself cause thermal resistance, and be an impedance to effective heat transfer from the component.

### BRIEF DESCRIPTION OF THE INVENTION

According to an exemplary embodiment, a heat sink assembly is provided that includes a base having first and second surfaces, and a dimension therebetween extending substantially perpendicular to each of the first and second surfaces. The base includes an opening extending therethrough and an insert received in the opening, wherein the insert has opposite first and second surfaces separated by a distance substantially equal to the dimension. The base is fabricated from a first material and the insert is fabricated from a second material.

Optionally, the base may be fabricated from aluminum, and the insert may be fabricated from copper. Additionally, the base may be substantially rectangular, and the insert may be substantially circular, wherein the base surrounds the insert. A fin structure may directly contact the first surfaces of each of the base and the insert. Optionally, a plurality of fins may be individually crimped to each of the base and the insert.

According to another exemplary embodiment, a heat sink assembly for cooling an electronic component includes a base having a top surface and a bottom surface, wherein at least a portion of the bottom surface engages the electronic component. The base includes a first portion fabricated from a first material and a second portion fabricated from a second material, wherein each of the first and second portions extend substantially an entire distance between the top and bottom surfaces.

According to a further exemplary embodiment, a heat sink assembly for an electronic component is provided. The heat sink assembly includes a rectangular base fabricated from a first material, and a cylindrical insert fabricated from a second material, wherein the insert is mounted to said base and is engaging the electronic component. Fins extend over the base and the insert and directly contact each of the base and the insert.

### BRIEF DESCRIPTION OF THE DRAWINGS

FIG. 1 is a bottom perspective view of a heat sink assembly formed in accordance with an exemplary embodiment of the present invention.

FIG. 2 is a top perspective view of the heat sink assembly shown in FIG. 1.

FIG. 3 is a top plan view of an exemplary base plate and fin structure for the heat sink assembly shown in FIG. 1.

FIG. 4 is an end elevational view of the base plate and fin structure shown in FIG. 3 along line 4-4.

FIG. 5 is an end elevational view of the base plate and fin structure shown in FIG. 3 along line 5-5.

### DETAILED DESCRIPTION OF THE INVENTION

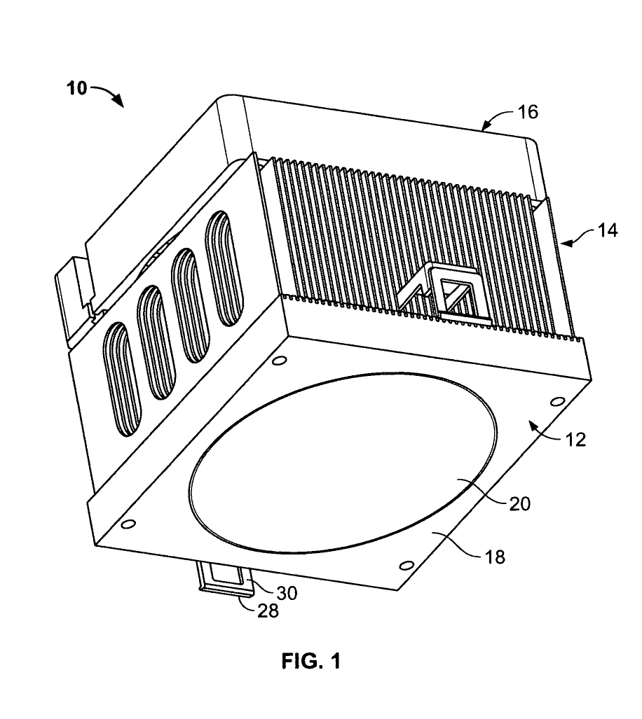

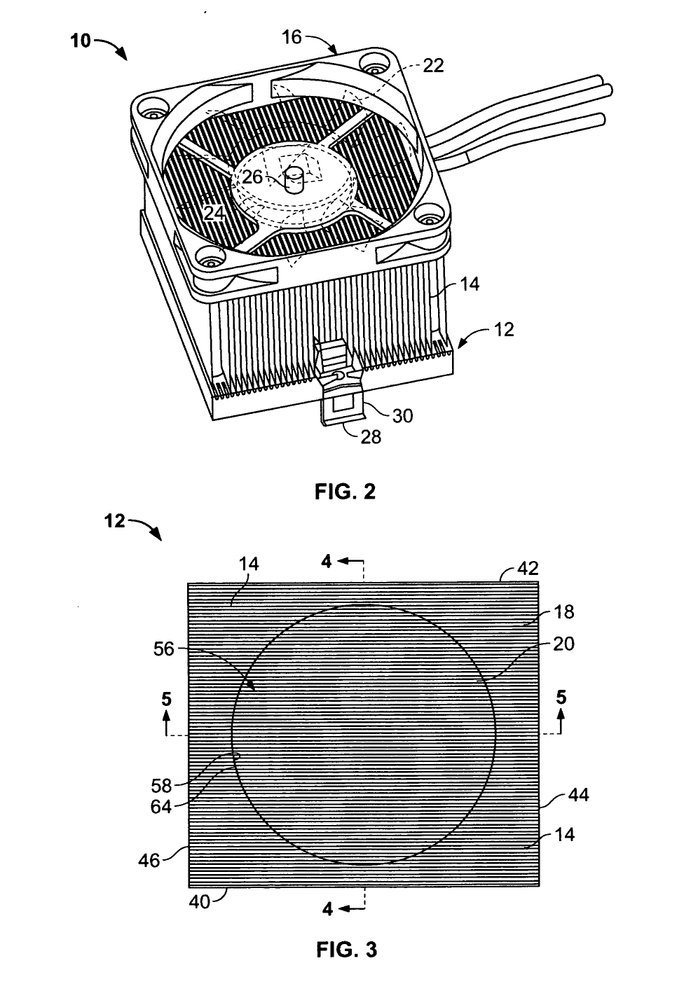

FIG. 1 is a bottom perspective view of a heat sink assembly 10 for drawing and dissipating heat from a heat generating component or heat source (not shown). FIG. 2 illustrates a top perspective view of the heat sink assembly 10. The heat sink assembly 10, as explained below, more effectively cools electronic devices and components than known heat sink assemblies.

In an illustrative embodiment, the heat sink assembly 10 includes a base plate 12, a number of fins 14 extending substantially vertically from the base plate 12, and a fan assembly 16 for circulating air over the fins 14 and the base plate 12. The base plate 12 is fabricated from metal, such as aluminum or copper, for example, and the base plate 12 is substantially rectangular in an illustrative embodiment. For improved heat dissipation performance, the base plate 12 includes a first portion, or base, 18 and a second portion, or insert, 20 fitted into the base 18. The second portion 20 may also be referred to hereinafter as a slug or a plug. In use, the insert 20 is placed in contact with the component to be cooled. The insert 20 is fabricated from a metal having a higher thermal conductivity than the base 18. Thus, for example, if the base 18 is fabricated from aluminum the insert 20 may be fabricated from copper or silver. If the base 18 is fabricated from copper or silver, then the insert may be fabricated from another metal or alloy having a higher thermal conductivity. It is recognized that the base 18 and the insert 20 may be fabricated from a variety of metals, alloys, and materials in various alternative embodiments without departing from the scope and spirit of the invention.

The fins 14 are thin vertical plate members fabricated from metal, such as aluminum in an exemplary embodiment, and the fins 14 are coupled to the base 18 and/or the insert 20 in a spaced apart relationship to one another. In the exemplary embodiment, the fins 14 are in abutting contact with both the base 18 and the insert 20. The fins 14 may be attached to the base plate 12 via a known process or technique, such as crimping and the like. In one embodiment, the fins 14 and the base 18 are each fabricated from the same material such as aluminum. As such, aluminum fins 14 may be directly coupled to a copper insert 20 for enhanced heat transfer from the base plate 12 to the fins 14. In another embodiment, the fins 14 and the insert 20 are fabricated from the same material such as copper. In another embodiment, the fins 14 are fabricated from a different material than both the base 18 and the insert 20. In yet another embodiment, adjacent fins 14 may be fabricated from different materials, or each fin 14 may be fabricated from multiple materials.

The fan assembly 16 includes a number of vanes 22 extending from a hub 24 that is rotationally mounted to a shaft 26. Power is supplied to the fan assembly 16 to energize a motor to rotate the hub 24 and the vanes 22 about the shaft 26 to circulate air downward upon the outer surfaces of the fins 14 and the base plate 12. When the base plate 12 is located in contact with a heat generating electronic component (not shown in FIG. 1), such as, for example, a processor chip, heat generated from the electronic component is transferred to the base plate 12 and to the fins 14, thereby cooling the electronic component in operation.

A resilient clip 28 extends across opposite sides of the base plate 12 and in between some of the fins 14. The clip 28 includes a latch member 30 that secures the clip 28 to a mounting feature (not shown) on, for example, a circuit board (not shown) wherein an electronic component to be cooled by the heat sink assembly 10 is installed. Alternatively, the heat sink assembly 10 is coupled directly to a component or a retention device mounted to the board to be cooled. In either case, the clip 28 applies a force to ensure a normal contact force between the base plate 12, and more specifically the insert 20, and the heat source to be cooled.

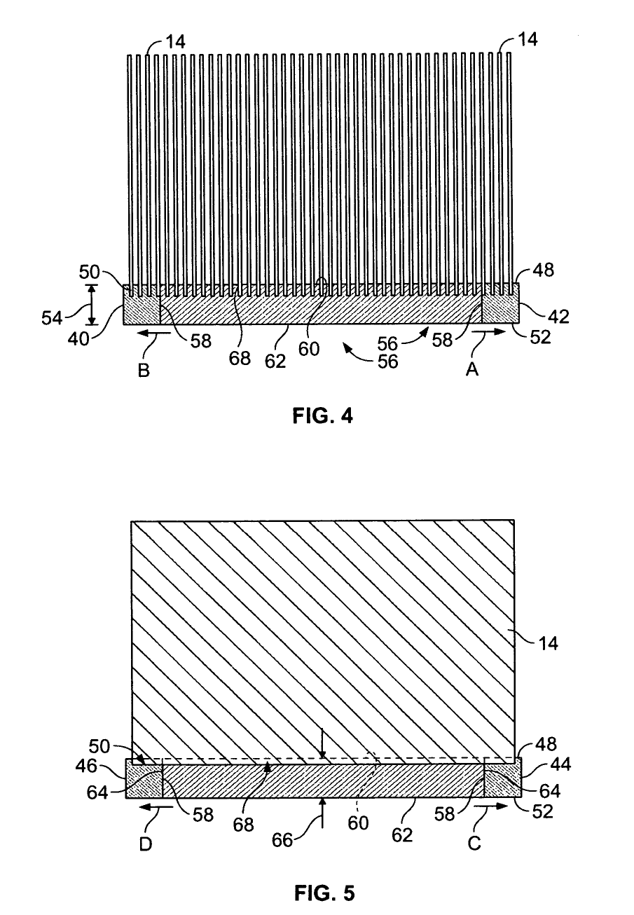

FIG. 3 is top plan view of the base plate 12 and the fins 14, and FIGS. 4 and 5 are cross sectional views of the base plate 12 and fins 14 taken along lines 4-4 and 5-5 in FIG. 3. The base plate 12 includes the base 18 and the insert 20. The base 18 includes a first pair of opposite side edges 40 and 42 and a second pair of opposite side edges 44 and 46 in a substantially rectangular arrangement. The base 18 includes a top surface 48 including a number of rectangular slots 50 therein arranged substantially parallel to one another and extending between the side edges 40 and 42. The slots 50 receive the fins 14 to position the fins 14 in a desired orientation relative to the base plate 12. The base 18 also includes a bottom surface 52 extending substantially parallel to the top surface 48 and spaced apart from the top surface 48 by a distance 54 measured perpendicularly to each of the surfaces 48 and 52. The distance 54 defines the thickness of the base 18.

The base 18 includes an elongated opening or slot 56 extending completely through the base 18 between the top and bottom surfaces 48 and 52, respectively. The opening 56 is defined by a side wall 58 extending substantially perpendicularly from each of the top and bottom surfaces 48 and 52 and having a height that is substantially equal to the thickness of the base 18. In the illustrative embodiment, the opening 56 is substantially cylindrical and has a diameter that is less then the width of the base 18. As such, the base 18 completely surrounds the opening 56 as the opening 56 is positioned a distance from each of the side edges 40, 42, 44, and 46. However, in alternative embodiments, the opening 56 may have any other size and shape depending on the particular application. For example, in one embodiment, the opening 56 may be substantially rectangular. In another embodiment, the opening 56 may be polygonally shaped. In other embodiments, the opening 56 may extend to at least one of the side edges 40, 42, 44, and/or 46 such that the opening 56 defines an outer edge of the base 18. In other embodiments, the opening may have side walls 58 that are tapered from the top and/or bottom surfaces 48 and/or 52.

The insert 20 includes a pair of opposite top and bottom surfaces 60 and 62 extending substantially parallel with one another and separated by a side wall 64. The side wall 64 extends substantially perpendicularly to each of the top and bottom surfaces 60 and 62 for a distance 66 that defines the thickness of the insert 20. In one embodiment, the distance 66 is substantially equal to the distance 54 such that the base 18 and the insert 20 have substantially equal thicknesses. The side wall 64 is oriented such that the insert 20 has a substantially cylindrical shape. However, it is realized that the insert 20 may have a variety of shapes and sizes depending on the particular application. Moreover, the shape and size of the insert 20 is determined based upon the weight requirements for the particular application as the weight of the insert 20 may be greater than the weight of the base 18.

The top surface 60 includes a number of rectangular slots 68 therein arranged substantially parallel to one another. The slots 68 are substantially aligned with corresponding slots 50 in the base 18 when the base plate 12 is assembled. The slots 68 receive the fins 14 to position the fins 14 in a desired orientation relative to the base plate 12. As such, the fins 14 are directly coupled to, and have a surface engagement with, the insert 20, thereby enhancing the thermal performance of the heat sink assembly 10. Moreover, because the fins 14 are directly coupled to the insert 20, a direct thermal path is defined from the component to the heat dissipating fins 14 through the insert 20. Specifically, because the fins 14 are directly engaged with the surface of the insert 20, which is fabricated from a metal having a higher thermal conductivity than the base 18, and which is placed in direct contact with the component (not shown) to be cooled, the heat is transferred directly from the component to the fins 14 via the insert 20. In one embodiment, the fins 14 are crimped to both the base 18 and the insert 20.

In the illustrative embodiment, the insert 20 is mounted within the opening 56. The insert 20 may be shrink fit into the opening 56 such that the insert 20 and the base 18 are coupled to one another. In other embodiments, the insert 20 and the base 18 may be coupled in another manner, such as, for example, crimping, soldering, adhering, or the like. In an exemplary embodiment, the insert 20 is coupled to the base 18 such that the side walls 64 and 58, respectively, are in substantial contact with one another. As such, a thermal interface is defined between the insert 20 and the base 18. Moreover, heat may be transferred across the thermal interface to enhance heat dissipation by the heat sink assembly 10, such as in the directions shown by arrows A, B, C and D. Furthermore, the insert 20 substantially eliminates gaps or voids between the base 18 and the insert 20 when assembled, as the contact along the thermal interface between the insert 20 and the base 18 is reduced. Specifically, the base 18 and the insert 20 interface along a surface extending perpendicularly through the base plate 12. Moreover, there is no interface between the base 18 and the insert 20 along the top surface 60 of the insert 20. As such, the elimination of voids between the insert 20 and the base 18 eliminates air pockets having a high resistance between the inserts 20 and the base 18, thereby improving heat transfer efficiency and the heat transfer capacity of the heat sink assembly 10.

The embodiments thus described provide a heat sink assembly 10 including a base plate 12 and a plurality of fins 14 for cooling an electronic component. The base plate 12 includes a base 18 having an opening 56 extending therethrough and an insert 20 received in the opening 56. The insert 56 is placed in direct contact with the electronic component being cooled. The base 18 is fabricated from a first material such as aluminum and the insert 20 is fabricated from a second material, such as copper. The fins 14 extend along and are directly coupled to the top surfaces 48 and 60 of each of the base 18 and the insert 20. As such, heat is transferred directly from the component to the fins 14 via the insert 20. As a result, the thermal performance of the heat sink assembly 10 is enhanced as the number of thermal interfaces is reduced, and associated thermal resistance, is reduced in comparison to known heat sink assemblies having inserts of higher thermal conductivity than the heat sink base.

While the invention has been described in terms of various specific embodiments, those skilled in the art will recognize that the invention can be practiced with modification within the spirit and scope of the claims.

What is claimed is:

1. A heat sink assembly comprising a base having first and second surfaces, and a dimension therebetween extending substantially perpendicular to each of said first and second surfaces, said base including an opening extending therethrough and an insert received in said opening, wherein said insert has opposite first and second surfaces separated by a distance substantially equal to said dimension, wherein said base is fabricated from a first material and said insert is fabricated from a second material.

2. The heat sink assembly of claim 1, wherein said base is fabricated from aluminum.

3. The heat sink assembly of claim 1, wherein said insert is fabricated from copper.

4. The heat sink assembly of claim 1, wherein said base surrounds said insert.

5. The heat sink assembly of claim 1, wherein said base is substantially rectangular.

6. The heat sink assembly of claim 1, wherein said insert is substantially circular.

7. The heat sink assembly of claim 1, wherein said base and said insert are press fit together.

8. The heat sink assembly of claim 1, further comprising a fin structure directly contacting the first surfaces of each of said base and said insert.

9. The heat sink assembly of claim 1, further comprising a plurality of fins individually crimped to each of said base and said insert.

10. A heat sink assembly for cooling an electronic component, said heat sink assembly comprising a base having a top surface and a bottom surface, wherein at least a portion of the bottom surface engages the electronic component, said base comprises a first portion fabricated from a first material and a second portion fabricated from a second material, wherein each of said first and second portions extend substantially an entire distance between said top and bottom surfaces.

11. The heat sink assembly of claim 10, wherein said second portion is encapsulated by said first portion.

12. The heat sink assembly of claim 10, wherein said first and second portions have a substantially equal thickness

13. The heat sink assembly of claim 10, wherein said first portion has an opening extending fully between the top and bottom surfaces, said second portion is press fit into the opening.

14. The heat sink assembly of claim 10, further comprising a fin assembly directly contacting each of said first portion and said second portion.

15. The heat sink assembly of claim 10, further comprising a plurality of fins individually coupled to each of said first and second portions.

16. The heat sink assembly of claim 10, further comprising a plurality of fins individually engaging only said first portion.

17. The heat sink assembly of claim 10, further comprising a plurality of fins individually engaging only said second portion.

18. A heat sink assembly for an electronic component, said heat sink assembly comprising:
a rectangular base fabricated from a first material;
a cylindrical insert fabricated from a second material, said insert mounted to said base and engaging the electronic component; and
fins extending over said base and said insert and directly contacting each of said base and said insert.

19. The heat sink assembly of claim 18, wherein said base has an opening extending therethrough, said insert mounted within the opening.

20. The heat sink assembly of claim 18, wherein said base surrounds said insert.
